(19) United States
(12) Patent Application Publication
(10) Pub. No.: US 2010/0163186 A1
(43) Pub. Date: Jul. 1, 2010

(54) Plasma Processing Apparatus

(76) Inventors: Tooru Aramaki, Kudamatsu (JP); Ryoji Nishio, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/691,855

(22) Filed: Jan. 22, 2010

Related U.S. Application Data
(63) Continuation of application No. 11/844,377, filed on Aug. 24, 2007.

(30) Foreign Application Priority Data
Mar. 30, 2007 (JP) 2007-090137

(51) Int. Cl. C23F 1/08; C23C 16/00

(52) U.S. Cl. 156/345.33; 118/723 VE

(57) ABSTRACT

A plasma processing apparatus wherein a layer structure consisting of plural layers formed in stack one upon another on a semiconductor wafer placed on the sample holder located in the process chamber, is etched with plasma generated in the process chamber by supplying high frequency power to the electrode disposed in the sample holder, the apparatus comprising a ring-shaped electrode disposed above the electrode and around the periphery of the top portion of the sample holder, an outer circumferential ring of dielectric material disposed above the ring-shaped electrode and opposite to the plasma, and a power source for supplying power at different values to the ring-shaped electrode depending on the sorts of layers of the layer structure.

### CROSS REFERENCE TO RELATED APPLICATION

This application is a continuation application of U.S. application Ser. No. 11/844,377, filed Aug. 24, 2007, the contents of which are incorporated herein by reference.

### BACKGROUND OF THE INVENTION

This invention relates to a plasma processing apparatus wherein a sample in the form of a circular disk such as a semiconductor wafer is placed in the process chamber in the vacuum vessel and the sample is processed with plasma formed in the process chamber. It relates more particularly to a plasma processing apparatus wherein the sample is processed while it is being placed on the upper surface of the sample holder located in the depressurized process chamber.

In such a plasma processing apparatus, the process gas fed into the process chamber to process the sample is excited by the electric or magnetic field developed in the process chamber so that plasma is formed, and then the chemical and/or physical interactions between the plasma particles and the material of the sample surface will allow at least one of the layers formed in the sample surface and supposed to be processed to be etched, for example. During this process, the process chamber will contain not only the plasma particles but also plural other chemical substances created through the above mentioned interaction and the reactions among the plasma particles. Some of the thus created chemical substances are adhesive and they usually are known to adhere to and deposit onto the sample surface and the inner surface of the process chamber.

Such deposited adhesive substances can be used as an auxiliary means to process the sample surface in a desired pattern. But if the adhesive substance is deposited excessively on the inner surface of the process chamber and if its part peels off to form fragments, they may adhere to the processed surface of the sample or they may attach to other places and then migrate to another sample as foreign material. Accordingly, the yield of the process will be lowered. A technique for solving such a problem is disclosed in Japanese Patent document: JP-A-2005-277369.

JP-A-2005-277369 discloses the technique wherein the amount of adhesion of substances especially on the peripheral, lower and upper surfaces of the sample can be decreased. According to the teaching of the document, in order to control the thickness of the sheath formed during processing above the upper surface of the focus ring located around the sample resting surface of the sample holder, a ring of insulating material is placed beneath the focus ring so as to adjust the potential over the surface of the focus ring. With this adjustment configuration, the distribution of the electric field over, under and near around the periphery of the sample is adjusted so that electric field may be developed to remove the adhesive material deposited on the lower surface of the sample periphery by attracting the charged particles of plasma toward and causing the charged particles to bombard, the lower surface of the sample. On the other hand, Japanese Patent document: JP-A-2006-245510 discloses the technique wherein a high frequency power is supplied to the focus ring itself to establish a bias potential around the sample periphery and the supplied high frequency power is adjusted to properly change the developed electric field in such a manner that the adhesive substance deposited on the sample periphery may be removed.

### SUMMARY OF THE INVENTION

According to the conventional technique disclosed in JP-A-2005-277369, the change in the process condition causes the change in the thickness of the sheath formed above the sample, the shapes of the equipotential surfaces and the heights of the equipotential surfaces, with the result that the same capability of removing the adhesive substance as achieved before the process change can be no longer achieved with the same thickness of the insulating material when the electric field near around the periphery of the sample changes. Accordingly, the plural layers formed on the sample substrate must be continuously processed. When it is necessary to change processing conditions depending on the sorts of layers, this conventional technique still suffers a problem that the adhesive substances deposited on the outer periphery of the sample cannot be satisfactorily removed. Further, with the conventional technique, there is a possibility that the sample itself is corroded in the process of removing the adhesive substances. Therefore, the shape controllability in processing will also become poor.

According to the conventional technique disclosed in JP-A-2006-245510, the focus ring is made of semiconductor material since if it is made of conductive material such as metal, it tends to interact intensely with the particles in plasma and therefore to be fast worn out. When, however, high frequency power is supplied to the focus ring of semiconductor through the electrode in contact with the focus ring, the high frequency power is hard to reach the part of the focus ring remote from the electrode. Consequently, there is a possibility that the removal of the adhesive substances becomes uneven near along the inner periphery of the focus ring, that is, near along the outer periphery of the sample in the form of a roughly circular disk. These conventional techniques have not given sufficient consideration to a countermeasure against these problems.

One object of this invention is to provide a plasma processing apparatus which can uniformly remove the adhesive substances deposited on the sample surface and therefore enjoy an improved process yield. Another object of this invention is to provide a plasma processing apparatus which can provide a highly uniform processing effect on the surface of and in the major surface direction of, the disk-like sample. Still another object of this invention is to provide a plasma processing apparatus wherein the capability of removing adhesive substances is compatible with the accuracy of fine working.

The objects described above can be attained by a plasma processing apparatus wherein a layer structure consisting of plural layers formed in stack one upon another on a semiconductor wafer placed on the sample holder located in the process chamber, is etched with plasma generated in the process chamber by supplying high frequency power to the electrode disposed in the sample holder, the apparatus comprising a ring-shaped electrode disposed above the electrode and around the periphery of the sample resting surface of the sample holder, an outer circumferential ring of semiconductor material disposed above the ring-shaped electrode and opposite to the plasma, and a power source for supplying power at different values to the ring-shaped electrode depending on the sorts of layers formed on the semiconductor wafer.

Further, the objects described above can be attained by a plasma processing apparatus wherein the sample holder in the shape of cylinder has its top portion reduced in diameter, the surface of the top portion serving as a sample resting surface, and when the wafer is processed, inert gas is supplied into the process chamber through the gap between the outer circumferential ring and the lower surface of the outer periphery of the wafer extending a little beyond the periphery of the sample resting surface of the top portion of the sample holder in the radial direction. In addition, the objects described above can be attained by a plasma processing apparatus comprising the power source which can supply power having different average values to the ring-shaped electrode depending on the sorts of the layers of the layer structure of the semiconductor wafer.

The objects described above can also be attained by a plasma processing apparatus comprising the power source which can supply at least two types of power having different values to the ring-shaped electrode and which supplies the two types of power in different ratios depending on the sorts of the layers of the layer structure of the semiconductor wafer. The plasma processing apparatus according to this invention can suitably be applied to process the layer structure comprising an uppermost photoresist layer serving as mask, a layer underlying the masking layer and having a lower etching speed, and a layer underlying the layer having the lower etching speed and having a faster etching speed.

The plasma processing apparatus according to this invention can suitably be applied also to process the layer structure comprising an uppermost photoresist layer, a first layer underlying the photoresist layer and to be etched with the photoresist layer used as mask, and a second layer underlying the first layer, having an etching speed higher than the etching speed for the first layer, and to be etched with the first layer used as mask.

The object of this invention can also be attained by a plasma processing apparatus wherein the value of the power supplied to the ring-shaped electrode when the layer having the lower etching speed is processed, is made smaller than the value of the power supplied to the ring-shaped electrode when the layer having the higher etching speed is processed. The object of this invention can yet be attained by a plasma processing apparatus wherein the difference between the potential over the ring-shaped electrode and the potential over the wafer, developed when the layer having the lower etching speed is processed, is made smaller than the difference between the corresponding potentials developed when the layer having the higher etching speed is processed. The object of this invention can still be attained by a plasma processing apparatus wherein the value of the power supplied to the ring-shaped electrode when the first layer is processed is made smaller than the value of the power supplied to the ring-shaped electrode when the second layer is processed. The object of this invention can still yet be attained by a plasma processing apparatus wherein the difference between the potential over the ring-shaped electrode and the potential over the wafer, developed when the first layer is processed, is made smaller than the difference between the corresponding potentials developed when the second layer is processed.

Other objects, features and advantages of the invention will become apparent from the following description of the embodiments of the invention taken in conjunction with the accompanying drawings.

### BRIEF DESCRIPTION OF THE DRAWINGS

FIG. 1 shows in top view the overall structure of a vacuum processing apparatus as an embodiment of this invention;

FIG. 2 schematically shows in vertical cross section the structure of a plasma processing apparatus as an embodiment of this invention;

FIG. 3 schematically shows in vertical cross section the structure of the sample holder around the periphery of a sample placed on the sample holder in the embodiment shown in FIG. 2;

FIG. 4 schematically shows in vertical cross section the structure of the sample holder around the periphery of a sample placed on the sample holder as another embodiment of this invention;

FIG. 5 schematically shows a system for controlling the feed of gas used in the embodiment shown in FIG. 4;

FIGS. 6A through 6E are operational diagrams illustrating the shift with time of processing operations taking place in the embodiment shown in FIG. 2;

FIGS. 7A and 7B schematically show the structures of the layers in the sample surfaces to be processed by the plasma processing apparatus shown in FIG. 2;

FIG. 8 schematically shows in vertical cross section the structure of a plasma processing apparatus as another embodiment of this invention; and

FIG. 9 schematically shows in vertical cross section the structure of a plasma processing apparatus as a modified example of the embodiment shown in FIG. 8.

### DESCRIPTION OF THE EMBODIMENTS

This invention will now be described in detail by way of embodiment with reference to the attached drawings.

### Embodiment 1

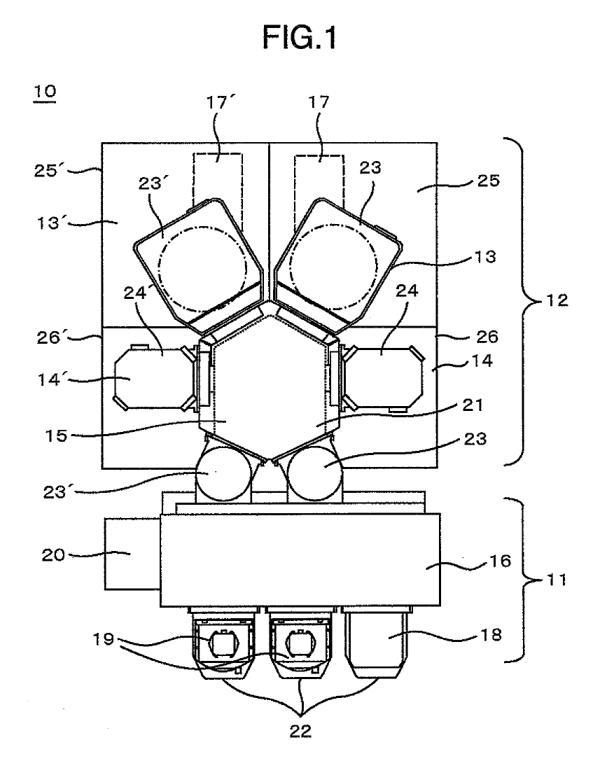

The first embodiment of this invention will be described with reference to FIGS. 1 through 7.

As shown in FIG. 1, a vacuum processing apparatus 10 according to this invention can be roughly divided into two blocks, front block and rear block. The front block, located near the bottom of FIG. 1, of the vacuum processing apparatus 10 is usually placed in a clean room and faces the conveyer line that carries the cassette encasing therein a semiconductor wafer as a sample substrate to be processed. Along the conveyer line are arranged plural vacuum processing apparatuses 10 and other processing apparatuses to form a so-called manufacturing line.

The front block is referred to as an atmospheric pressure block 11. For this block first receives a wafer under the atmospheric pressure before it is transferred into the depressurized chamber of the vacuum processing apparatus 10. The rear block, located near the top of FIG. 1, of the vacuum processing apparatus 10 is referred to as a processing block 12, which communicates with the atmospheric pressure block 11.

The atmospheric pressure block 11 includes a housing 16 which incorporates therein a transfer robot (not shown). Onto the front surface of the housing 16 are attached plural (three in this embodiment) cassette holders 22 which support thereon cassettes 19 encasing wafers to be processed or to be cleaned and a cassette 18 encasing a dummy wafer. Onto the rear surface of the housing 16 are attached lock chambers 27 and 27′ which serve as part of the processing block 12 and as an interface whose internal is variable in structure so as to reciprocate a wafer between the internal of the atmospheric pressure block 11 and the internal of the processing block 12.

The transfer robot incorporated in the housing 16 serves to transfer wafers from the cassettes 18, 19 to the lock chambers 27, 27′, or vice versa. A position adjuster 20 is attached onto the side surface of the housing 16 of the atmospheric pressure block 11. The wafer to be transferred by the transfer robot has its position adjusted in the position adjuster 20 according to the standard wafer position to be taken in the cassettes 18,19 or the lock chambers 27, 27′.

The processing block 12 comprises a vacuum transfer chamber 21 whose top view is of polygon (pentagonal in this embodiment) and in which wafers are transferred while its internal is depressurized to a high vacuum, and an atmospheric pressure transfer unit 15 whose internal is kept at atmospheric pressure, which is located on the front side of the vacuum transfer chamber 21 and which has the lock chambers 27 and 27′ for communicating the atmospheric pressure block 11 with the vacuum transfer chamber 21. The side surfaces of the polygonal vacuum transfer chamber 21 are connected with plural lock chambers 27 and 27′ which communicate with the atmospheric pressure transfer unit 15, the atmospheric pressure block 11 and processing units 13, 13′, 14 and 14′ having therein process chambers wherein wafers are processed in depressurized vessels. These processing units can be depressurized to a high vacuum and the processing block 12 is used to process wafers in vacuum.

The processing units 13 and 13′ of the processing block 12 according to this embodiment are arranged as attached to the adjacent side surfaces at rear of the hexagonal vacuum transfer chamber 21. These processing units 13 and 13′ are provided with process chambers in which wafers are etched before they are transferred from the cassettes 19 to the processing block 12.

The processing units 14 and 14′ of the processing block 12 are arranged as attached to the opposite side surfaces of the hexagonal vacuum transfer chamber 21. In this embodiment, these processing units 14 and 14′ serve as ashing process units provided respectively with process chambers wherein wafers transferred from cassette 19 or the processing units 13 and 13′ are subjected to ashing treatment. The processing units 13, 13′, 14 and 14′ are detachably mounted on the atmospheric pressure transfer unit 15. The vacuum transfer chamber 21 is the space through which wafers are transferred between a lock chamber (vacuum chamber or vacuum vessel) 23 or 23′ and the processing units 13, 13′, 14 and 14′ under a depressurized condition.

The plural lock chambers 27 and 27′ are connected with an air evacuator (not shown) such as a vacuum pump and the internals thereof can be depressurized to any pressure value between the atmospheric pressure and a high vacuum while containing sample wafers to be processed. Gate valves (not shown) turn on and off the gaseous communication between the atmospheric pressure block 11 or the housing 16 and the vacuum transfer chamber 21. These lock chambers 27 and 27′ have the same functions, and each of them may perform the operations both of increasing pressure change (unload) from vacuum to atmospheric pressure and of decreasing pressure change (load) from atmospheric pressure to vacuum. However, one of them may also be so designed as to perform only one of the operations according to desired specifications.

In this processing block 12, the processing units 13 and 13′ respectively have in them vacuum vessels 23 and 23′ housing process chambers wherein wafers are etched under depressurized condition. As described later, beneath the vacuum vessels 23 and 23′ are provided evacuating means for evacuating the process chambers housed in the vacuum vessels 23 and 23′. The processing units 13 and 13′ are fixedly supported on the floor on which the vacuum processing apparatus 10 is placed, by means of beds 25 and 25′ for supporting thereon the vacuum vessels 23 and 23′ and the evacuating means communicated thereto and by means of plural supporting pillars mounted on the beds 25 and 25′ for supporting the vacuum vessels 23 and 23′ by mechanically connecting the beds 25 and 25′ with the vacuum vessels 23 and 23′, respectively.

Further, above each of the vacuum vessels 23 and 23′ is, as described above, located a coil case housing a electromagnetic coil for developing magnetic field that produces plasma in the process chamber housed in the corresponding vacuum vessel. Furthermore, above the coil case are located a power source for supplying electric field into the process chamber and a microwave source including a wave guide for conducting electric field therethrough.

The processing units 14 and 14′ respectively have in them vacuum vessels 24 and 24′ housing process chambers which can be evacuated and wherein wafers are subjected to ashing treatment. Beneath each of the vacuum vessels 24 and 24′ is located an evacuating means for depressurizing the process chamber housed in the corresponding vacuum vessel. The processing units 14 and 14′ are fixedly supported by means of beds 26 and 26′ for supporting thereon the vacuum vessels 24 and 24′ and the evacuating means and by means of plural supporting pillars mechanically connecting the beds 26 and 26′ with the vacuum vessels 24 and 24′, respectively.

In the beds 25 and 25′ are located gas supply units 17 and 17′ which controllably feed process gas into the vacuum vessels 23 and 23′ to process samples. Similarly, in the beds 26 and 26′ are located gas supply units (not shown) which controllably feed process gas into the vacuum vessels 24 and 24′ to process samples.

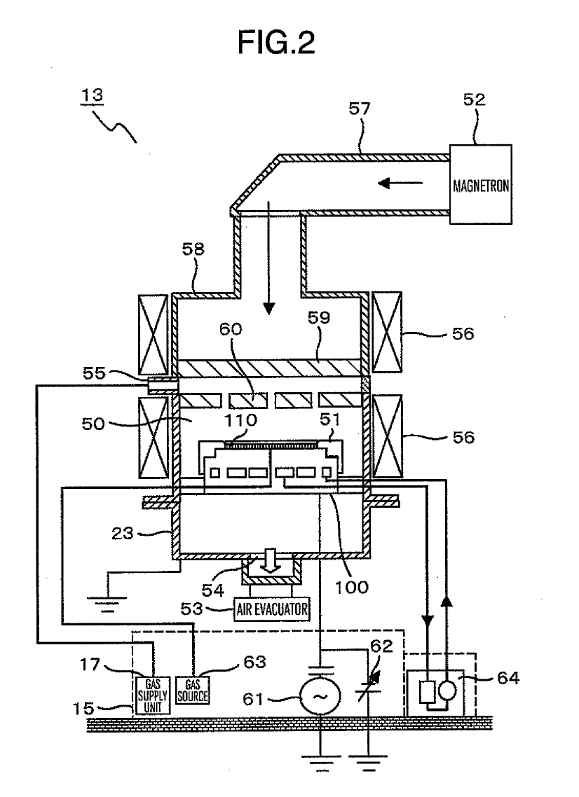

The structure of a plasma processing apparatus serving as the processing unit 13 or 13′ in the processing block 12 of the vacuum processing apparatus 10 will now be described with reference to FIG. 2. FIG. 2 schematically shows in vertical cross section the structure of the processing unit 13 shown in FIG. 1. The overall structure consists mainly of the bed 25, the vacuum vessel 23 located above the bed 25, and other items attached or located around the vacuum vessel 23. The vacuum vessel 23 located above the bed 25 has a process chamber 50 in it, which defines a roughly cylindrical space. The roughly cylindrical space contains a stage 51 including a sample holder 100 on which a disk-like sample of semiconductor wafer to be processed is placed.

The bed 25 located beneath the processing unit 13 contains a temperature adjuster 64 which feeds heat exchange medium into the internal of the sample holder 100 after having controlled its temperature; a high frequency power source 61 which develops bias potential over the sample 110 by supplying high frequency power to an electrode made of conductive material and disposed within the sample holder 100; and a DC power source 62 which supplies power for immobilizing, by means of electrostatic attraction, the sample 110 on a roughly circular disk-like dielectric film serving as the sample resting surface of the stage 51. The temperature adjuster 64 adjusts the temperature of the heat exchange medium discharged out of the sample holder 100 to a predetermined value and then feeds it into a duct having a rectangular cross section and having a spiral shape. Thus, the heat exchange medium flows through the coolant passage within the sample holder 100 while adjusting the temperatures of 9 the sample holder 100 and the sample 110 placed thereon through heat exchange, and then is discharged out of the sample holder 100 to return to the temperature adjuster 64.

In the bed 25 are located a gas source 63 of heat transfer gas fed into the space between the sample resting surface of the sample holder 100 and the lower surface of the sample 110, and a gas supply unit 17 for process gas fed into the process chamber 50 contained in the vacuum vessel 23. In this way, the bed 25 having a space to contain specific apparatuses is roughly rectangular in shape and its flat upper surface can bear thereon an operator who handles the vacuum vessel 23 and other apparatuses inside or outside the vessel 23.

A source of electromagnetic waves to establish electric field in the process chamber 50 and a means for generating magnetic field in the process chamber 50 are located above the vacuum vessel 23 disposed above the processing unit 13. An air evacuator 53 having a vacuum pump for evacuating the process chamber 50 to depressurize the internal thereof is located beneath the vacuum vessel 23. A shower plate 60 in the form of a roughly circular disk having a diameter larger than that of the disk-shaped sample 110 is disposed above like the ceiling of the process chamber 50, opposing to the sample resting surface of the sample holder 100. The shower plate 60 has plural through holes distributed concentrically over the plate 60 with respect to the virtual vertical center axis of the sample holder 100 or the sample 110 placed thereon. The process gas supplied from the gas supply unit 17 is fed through these through holes into the ceiling area of the process chamber 50.

A window member 59 in the form of roughly circular disk made of dielectric material, e.g. quartz, overlies the shower plate 60 at a predetermined distance from the shower plate 60. Electric field supplied from above is introduced through the window member 59 into the process chamber 50 below. The electric field established inside the process chamber 50 serves to turn into plasma the process gas fed into the space between the sample holder 100 and the shower plate 59 above. The roughly cylindrical space over the window member 59 of the vacuum vessel 23 has a specific shape that induces the resonance of the electric field supplied from an electromagnetic wave source placed above.

The zone inside the vacuum vessel 23 beneath the sample holder 100 is a space into which particles such as plasma, reactive gas and resultant substances produced through chemical reactions in the process chamber 50 housing the sample holder 100 are introduced. An opening 54 coupling to the air evacuator 53 is provided at the bottom of the vacuum vessel 23 so as to discharge the introduced particles out of the process chamber 50. In the passage between the opening 54 and the air evacuator 53 is provided plural rotatable blade-like flaps, whose rotation controls the aperture of the passage to control the evacuation of the process chamber 50 by means of the air evacuator 53.

A magnetron 52 as a source of electromagnetic waves fed into the process chamber 50 to establish electric field therein is located above the vacuum vessel 23. Electromagnetic waves generated by the magnetron 52 propagate through a wave guide 57 having a roughly rectangular cross section and extending first horizontally and then vertically, into the resonance space defined above the window member 59. Electric field developed in this resonance space as a result of resonance of the microwaves therein at a certain frequency is supplied through the window member 59 and the shower plate 60 into the process chamber below. Process gas supplied from the gas supply unit 17 is further fed through a process gas inlet port 55 into the space between the window member 59 and the shower plate 60. The process gas fills the space and then flows through the through holes of the shower plate 60 into the process chamber 50 to shroud the sample holder 100.

The sample 110 transferred to and placed on the sample holder 100 is attracted to the sample resting surface due to the electrostatic force generated in response to the power supplied from the DC power source 62. The process gas fed into the process chamber 50 is turned into plasma as a result of the interaction between the process gas and the combined effect of the microwaves supplied into the process chamber 50 and the magnetic field supplied into the process chamber 50 from the solenoid coils 56 located around and above the vacuum vessel 23. At least one of the layers formed on the surface of the sample 110, which is supposed to be processed, is etched by the thus generated plasma. During this etching process, a desired bias potential is developed over the sample 110 due to the high frequency power supplied from a high frequency power source 61 to the electrode disposed within the sample holder 100. In accordance with the potential difference between the bias potential and the potential of the plasma, the charged particles of the plasma are accelerated toward and bombard the surface of the sample 110 to promote anisotropic etching. As a result of this etching treatment, byproducts are generated in the process chamber 50.

Plasma, process gas and byproduct particles are transferred through the passage between the inner surface of the wall of the process chamber 50 of the vacuum vessel 23 and the side surface of the stage 51 into the space below the stage 51, and further discharged through the opening 54 out of the process chamber 50 by the action of the air evacuator 53. While the sample 110 is being processed, the supply of process gas through the operation of the gas supply unit 17 and the discharge of plasma etc. through the operation of the air evacuator 53 are controlled so that the pressure within the process chamber 50 can be adjusted to a desired pressure as a result of balance between the supply and the discharge. The side and bottom walls of the vacuum vessel 23 are both electrically grounded.

The opening 54 is roughly circular and approximately arranged concentric with respect to the virtual vertical center axis of the sample holder 100. In this embodiment, the process chamber 50, the window member 59, the shower plate 60, the sample holder 100, the opening 54 and the air evacuator 53 are arranged concentric with respect to the virtual vertical center axis. With this structure, the uniformity of process along the virtual concentric circles on the sample surface can be improved to better the yield of process. Further in this embodiment is provided a control apparatus (not shown) which is electrically coupled to plural sensors for monitoring the operations of the process unit 13 and other various pieces of hardware included in the vacuum processing apparatus 10, receives the signals from these sensors through a communication means, detects the operating conditions of the process unit 13 and other various pieces of hardware depending on the received signals, and transmits command signals for controlling the operating conditions through the communication means.

The byproducts generated as a result of the above described etching treatment have high potential energy and therefore highly adhesive. Such highly adhesive byproducts adhere to the inner surface of the wall of the process chamber 50. The deposited byproducts accumulate as the number of processed wafers increases. Therefore, it is customary for a user to clean the internal of the process chamber after opening the vacuum vessel 23 to the atmosphere when a certain number of samples have been processed. The adhesive byproducts may adhere to the surface of the sample 110 as well as the internal surface of the wall of the process chamber 50. Such byproducts adhering to the sample 110 may be removed from the sample while it is being transferred and make foreign materials to contaminate other samples or adhere again to the internal surface of the wall of the process chamber 50. When another sample is processed in the process chamber 50, the generated plasma may remove the byproducts from the internal surface of the wall of the process chamber 50 so that they adhere to the upper surface of the sample to contaminate it.

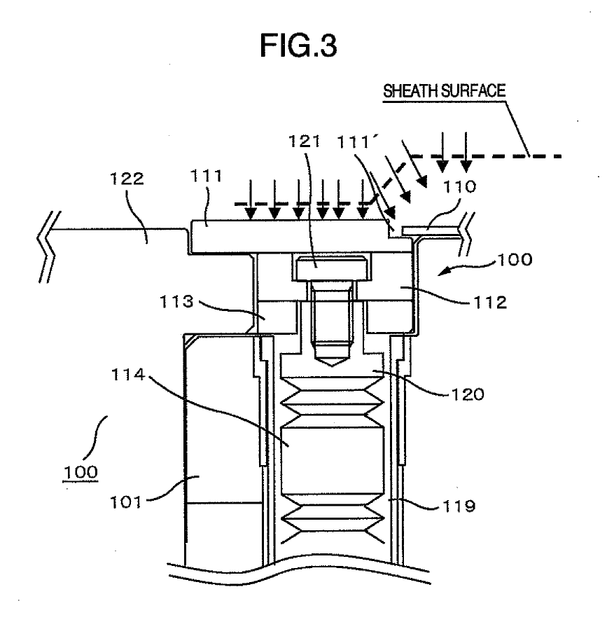

Of the byproducts created through the process of sample, those which have adhered to the upper surface of the sample 110 can be removed through the bombardment of the upper surface with charged particles such as ions accelerated in plasma according to the bias potential developed by the high frequency power supplied from the source 61. In order to remove the part of the byproducts which has adhered to such an area, e.g. the bottom surface of the sample, as not exposed to the plasma, such remover as charged particles are introduced to the area contaminated by the byproducts. In this embodiment, as shown in FIG. 3, a focus ring 111 is provided surrounding the periphery of the sample resting surface of the sample holder 100 and also encircling the periphery of the stage 51. The sample holder 100 has its top portion reduced in diameter and the upper surface of the top portion serves as the sample resting surface. The focus ring 111, roughly circular, made of semiconductor or dielectric material is disposed around the diameter-reduced top portion of the sample holder 100, encircling the periphery of the sample 110. In order to cover and protect the upper and side surfaces of the sample holder 100, a roughly circular susceptor ring 122 is provided around the outer periphery of the focus ring 111.

A power supply ring 112 made of conductive material is disposed under the focus ring 100 and around the top portion of the sample holder 100. A high frequency power source (not shown) supplies high frequency power for the power supply ring 112 and a bias potential is formed above the focus ring 111 resting on the power supply ring 112.

In this embodiment, the magnitude of the power supplied from the high frequency power source 61 to the sample holder 100 is made different from the magnitude of the power supplied from another high frequency power source to the power supply ring 112 disposed under the focus ring 111 so that the height of the sheath surface (equipotential surface) formed due to the bias potential distributed over the surface of the sample 110 is made different from the height of the sheath formed due to the bias potential at the focus ring 111. As shown in FIG. 3, the sheath surface (equipotential surface) over the sample 110 is located higher than the sheath surface over the focus ring 111. The sheath surface ascends from the inner periphery of the focus ring 111 toward the outer periphery of the sample 110. As shown with arrows in FIG. 3, as the charged particles travel perpendicular to the sheath surface, they impinge slant on the sample surface near the periphery of the sample 110 and vertical onto the upper surface of the sample 110 in the central area of the upper sample surface. Consequently, etching process is promoted by the charged particles impinging slant onto the upper surface of the sample 110 due to the ascending sheath surface formed along the periphery of the sample 110.

In this embodiment, the diameter of the sample resting surface that is the upper surface of the top portion of the sample holder 100 is set slightly smaller than that of the sample 110 which is normally a circular disk. Therefore, when a sample 110 is placed on the sample resting surface of the sample holder 100, the outer edge of the sample 110 overhangs the sample resting surface. Further, the inner peripheral part of the focus ring 111 has its upper surface descending toward the inner edge of the ring 111, i.e. being in the shape of a countersink or recessed like a counterbore 111′ cut concentrically with the inner opening of the ring 111. The lowest surface of the focus ring 111, corresponding to the innermost part of the ring 111 or the bottom of the recess 111′, is set slightly lower than the sample resting surface of the sample holder 100 and underlaps the outer edge of the sample resting properly on the sample resting surface of the sample holder 100. Namely, the inner diameter of the focus ring 111 is set larger than the diameter of the top portion of the sample holder 100 and smaller than the diameter of the sample 110.

As described above, as there is a fine gap between the lowest surface, i.e. the bottom of the recess 111′, of the focus ring 111 and the lower surface of the outer edge of the sample 110, the gap being provided for the tolerance in placing a sample on the sample resting surface, the charged particles traveling slant toward the sample 110 can enter the fine gap under the outer edge of the sample 110. The charged particles having entered into the gap can remove the byproducts adhering to the peripheral part of the sample 110 through the interaction with the surface of the materials enclosing the gap. In this embodiment, the bias potential formed by the focus ring 111 for controlling the impinging angle of the charged particles and the bias potential formed above the sample 110 can be arbitrarily changed by providing the high frequency power source for supplying power to the power supply ring 112, separately from the high frequency power source 61 for supplying power to the electrode within the sample holder 100.

The bias potential formed above the focus ring 111 may be arbitrarily changed by providing an impedance control means such as a variable capacitor in the power supply line to the power supply ring 112, thereby controlling the bias load with respect to the focus ring 111. In order for the arbitrarily variable bias potential to be able to distribute uniformly along the focus ring 111, the power supply ring 112 of conductive material, similar in shape to the focus ring 111, is disposed under and concentric with the focus ring 111 and supplied with electric power.

The shape of the focus ring 111 is preferably determined in such a manner that the sheath surface over the focus ring 111 is lower than the sheath surface over the sample 110, i.e. disk-like semiconductor wafer, near the outer periphery of the sample 110. For this purpose, the bottom surface of the recess 111′ provided in the inner periphery of the focus ring 111 as described above should preferably be made lower than the upper surface of the outer periphery, extending beyond the outer periphery of the sample resting surface, of the sample 110 resting on the sample holder 110, within a specified radius slightly larger than the radius of the sample 110. The specified radius is preferably equal to any radius ranging between the radius of the sample 110 and the radius of the sample 110 plus 20 mm.

In this invention, in order to lower the height of the sheath over the focus ring 111, the magnitude of the high frequency power for forming the bias potential over the focus ring 111 is set much greater than that of the high frequency power for forming the bias potential over the sample 110. The bias potential may start to form over the focus ring 111 while the byproducts are adhering to the surrounding items or when they have finished adhering to the surrounding items.

An insulation ring 113 is fittingly inserted in a vertical through hole 119 cut in the recessed base 101 of the sample holder 100 made of conductive material. A power supply shaft 120 has a fastening bolt 121 threaded into its upper portion and electrically coupled to the power supply ring 112 with the insulation ring 113 interposed in between. The insulation ring 113 is made of insulating material and has a shape similar to that of the power supply ring 112. The fastening bolt 121 rigidly fixes the insulation ring 113 in contact with the bottom surface of the power supply ring 112, with the upper portion of the power supply shaft 120 of conductive material inserted in the through hole penetrating the insulation ring 113. The power supply shaft 120 is pushed upward due to the thermal expansion caused as a result of heating by the supply of high frequency power. A heating adjustment mechanism 114 having bellows absorbs such thermal expansion in its compressible structure. The insulation ring 113 is used to prevent abnormal discharges due to the potential differences for controlling the bias other than that for the sample 110.

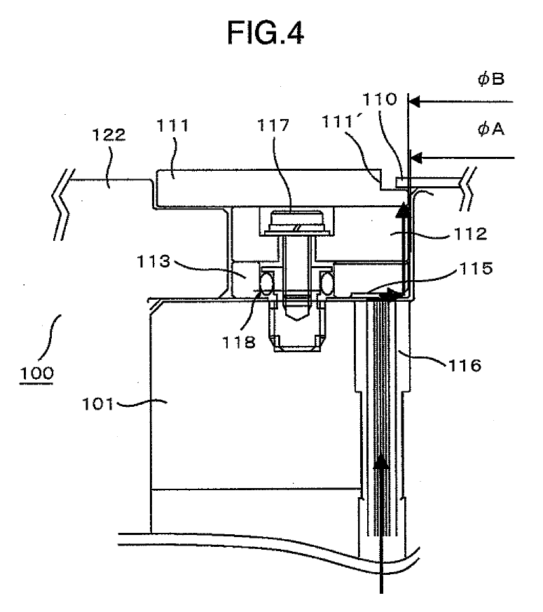

FIG. 4 schematically shows in vertical cross section the structure of the sample holder around the periphery of a sample placed on the sample holder as another embodiment of this invention. In this embodiment, a gas supply means is provided in the vicinity of the focus ring 111 disposed around the top portion of the sample holder 100 so as to feed gas into the space between the periphery of the sample 110 and the inner edge of the focus ring 111, the gas flowing from the lower side of the sample 110 toward the outer edge of the sample 110 to reduce the amount of byproducts adhering to the periphery of the sample 110. Namely, insulated gas supply bosses 116 are provided through the recessed base portion 101 of the sample holder 100 and around the top portion of the sample holder 100. The insulated gas supply bosses 116 are circumferentially equidistant from one another around the top portion of the sample holder 100. Gas is supplied out of the upper openings of the bosses 116 to push back toward the process chamber 50 the adhesive byproduct particles entering the space between the lower surface of the outer periphery of the sample 110 and the upper surface of the recess 111′ of the focus ring 111 from the process chamber 50.

The pressure of gas is relatively high in the insulated gas supply bosses 116 through which specific gas to flow toward the focus ring 111 pass. This high pressure gas makes it easy for abnormal electric discharges to take place. To prevent such abnormal discharges, the bore diameter of the boss is not more than 2 mm in this embodiment. Further, a gas feed line 115 is provided at the upper opening of each insulated gas supply boss 116 so as to uniformly feed and purge the gas supplied from each upper opening of the boss 116, along the inner periphery of the focus ring 111 and the outer periphery of the sample 110.

The gas feed line 115 is an annular groove cut in the bottom surface of the insulation ring 113 along the inner periphery of the ring 113 and opposite to the upper openings of the insulated gas supply bosses 116. The gas feed line 115 completes its shape with the annular groove, the upper surface of the recessed base 101 of the sample holder 100, on which the insulation ring 113 rests, and the lateral surface of the top portion of the sample holder 100. The gas entering the gas feed line 115 from the upper openings of the insulated gas supply bosses 116 first fills the gas feed line 115 and then part of the gas moves up toward the focus ring 111 through the gap between the insulation ring 113 and the lateral surface of the top portion of the sample holder 100. In this embodiment, the gap between the insulation ring 113 and the lateral surface of the top portion of the sample holder 100 circumferentially surrounds the top portion of the sample holder 100. The thickness of the gap in the radial direction is sufficiently smaller than the vertical thickness of the gas feed line 115 (the distance between the bottom of the annular groove and the upper surface of the recessed base 101 of the sample holder 100, and referred to later as the difference between φA and φB) so that the gas entering the gas feed line 115 may be distributed uniformly throughout the annular space. The gas feed line 115 plays a role as the buffer space for the supplied gas, that serves as the passage through which gas is distributed uniformly along the outer periphery of the sample 110.

In this embodiment, the insulation ring 113, except the surface of the groove serving as the gas feed line 115, is placed on and in contact with the upper surface of the recessed base 101 of the sample holder 100. The insulation ring 113 is fixedly pressed to the base 101 of the sample holder 100 below by means of fastening bolts 117 threaded from above into through holes cut equidistantly in the circumferential direction around the top portion of the sample holder 100. In order to prevent abnormal electric discharge from occurring around the peripheries of the inserted fastening bolts 117, the through holes of the insulation ring 113 are hermetically sealed with sealing members such as O-rings so that gas may not leak into the space between the focus ring 111 and the fastening bolts 117.

The fastening bolts 117 also serve to prevent the insulation ring 113 and the other parts resting thereon from vibrating due to the pressure of gas supplied through the insulated gas supply bosses 116 to the gas feed line 115.

As described above, abnormal electric discharge that may occur due to the difference in bias potential between the electrode disposed in the sample holder 100 and the fastening bolts 117 can be avoided by the combination of the insulated bosses and insulated bolts. However, insulated bolts, a weight and adhesive agent may be used for the same purposes.

Further, in this embodiment, the dimensions of φA and φB are important in that the gas flowing into the space between the sample 110 and the upper surface of the recess 111′ of the focus ring 111 must have a flow velocity greater than the travel velocity of the byproduct particles which enter the space to adhere to the periphery of the sample 110. When the sample 110 is etched, most adhesive byproducts consist mainly of chemical elements such as carbon C and fluorine F having relatively heavy molecular weights although they vary depending on the process conditions and/or the plasma conditions. In order to remove such deposition of byproducts, gas must be supplied in such a manner that the product of the molecular weight of the gas and the gas flow rate surpasses the adhesion capability, defined as the product of the molecular weight of the deposited byproduct and the velocity of the byproduct particles at the instant of adhesion.

Moreover, during such removal of byproduct deposition, it is necessary to reduce the influence on the plasma in which particles to process the sample surface in the process chamber 50 are generated. For this purpose, inert gas such as argon Ar or xenon Xe is supplied through the insulated gas supply bosses 116 in this embodiment. Further, the gas feed rate is chosen such that too much pressure may not be imposed on mechanical parts and that a large influence may not be given to the internal pressure of the process chamber 50 during the evacuation of the process chamber 50.

Gas species may preferably include inert gas such as helium He, argon Ar or xenon Xe. Helium may be used for its high heat transfer property. However, since gas having a heavy molecular weight is preferable to provide a value greater than the above described adhesion capability associated with the plasma particles of interest and since fluorocarbon CF is supposed to be a lightest seed of adhering byproducts, then gas having molecular weight heavier than that of argon Ar must preferably be used. For the same purpose, oxygen gas may be used. The flow rate of the gas is set equal to or less than the feed rate of the process gas for forming plasma in the space over the sample 110 in the process chamber 50. It should be noted that φA is less than the diameter of the sample 110, and φB exceeds φA but still remain less than the diameter of the sample 110, to prevent parts from being abraded by plasma. Moreover, it is preferable to set φA less than the diameter of the sample 110 and φB somewhere between φ(A+0.01) mm and φ(A+10) mm.

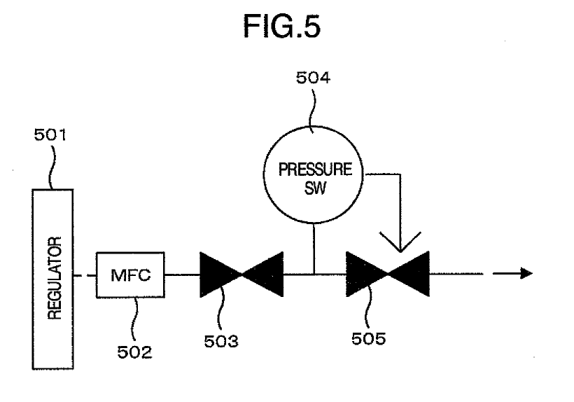

FIG. 5 schematically shows the structure of the passage for feeding gas to the insulated gas supply bosses 116. In this embodiment, a mass flow controller MFC 502 controls the flow of gas fed through the insulated gas supply bosses 116 to the gas feed line 115 in response to the instruction signal issued by a regulator 501 in accordance with the command signal from the control apparatus. Inert gas supplied from the MFC 502 flows toward the gas feed line 115 through valves 503 and 505 to open and close this passage. In this embodiment, MFC 502 is employed, but it may be replaced by a pressure control valve PCV in another embodiment. A pressure switch 504 may be provided between the valves 503 and 505 to prevent parts from breaking, and samples from being blown away or vibrating. In such a case, the pressure switch 504 detects the gas pressure in the passage and when an abnormal pressure is detected, the pressure switch 504 issues an instruction to the valve 505 to close the passage and therefore to stop the supply of the gas.

Alternatively, the pressure switch 504 may be replaced by a pressure gauge and the valves 503 and 505 may be operated in response to the output of the pressure gauge. The regulator 501 for the regulation of the primary pressure controls the flow rate and the pressure to prevent the parts along the passage from breaking.

The flow rate of the supplied inert gas is preferably between 2 ccm and 2000 ccm. That part of the inert gas passage in which potential difference occurs is build with insulating material and the inner diameter φ of the passage is preferably less than 1 mm. That part of the inert gas passage in which no potential difference occurs may be built with any suitable material. There is no specific regulation applicable to the choice of the material. In the latter case, larger diameter will be more preferable.

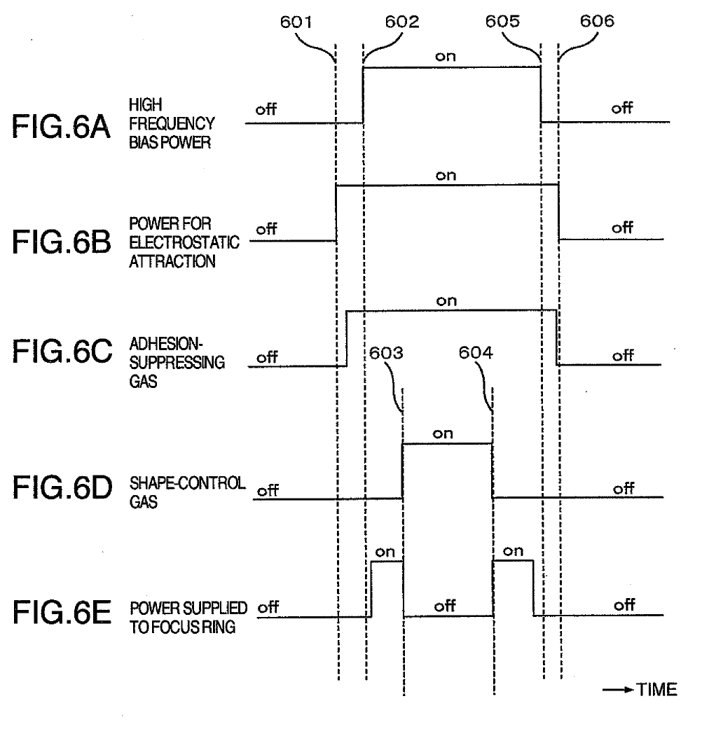

FIGS. 6A through 6E are operational diagrams illustrating the shift with time of operations for etching desired layers in the surface of the sample 110 in the plasma processing apparatus as this embodiment described hereto. In the process of the sample 110 shown in these figures, the sample 110 is placed on the arm of the transfer robot located in the vacuum transfer chamber 21 and transferred onto the sample holder 100 housed in the process chamber 50 whose internal is kept at a predetermined pressure.

Then, prior to the application of high frequency power to the electrode disposed in the sample holder 100 to form a bias potential, DC power is supplied from the DC power source 62 to the sample holder 100 so as to immobilize the sample 110 on the dielectric layer serving as the sample resting surface on the sample holder 100 due to electrostatic attraction (at instant 601). After the sample 110 has been secured onto the sample holder 100, reactive gas for etching a desired layer is introduced through the shower plate 60 into the process chamber 50. Simultaneously, inert gas whose flow rate is controlled by the MFC 502 in response to the instruction from the regulator 501 is fed into the gas feed line 115 and then discharged through the space between the outer periphery of the sample 110 and the focus ring 111 into the process chamber 50.

Thereafter, electric field is supplied through the shower plate 60 and developed in the process chamber 50, and magnetic field generated by the solenoid coil 56 is likewise established in the process chamber 50, so that plasma is formed above the sample 110 in the process chamber 50. High frequency power is supplied from the high frequency power source 61 to the electrode in the base 101 and the charged particles of the plasma are accelerated toward the surface of the sample 110 to initiate the processing of the desired layer (at instant 602). When sensors detect the completion of the desired process, the supply of the high frequency power is stopped (at instant 605) and then the DC power for electrostatic attraction is interrupted (at instant 606) to release the electrostatic attraction of the sample 110. Thereafter, the processed sample 110 is lifted up from the sample resting surface of the sample holder 100 and transferred out of the process chamber 50.

During the process of the sample 110, the DC power for providing electrostatic attraction is continuously supplied to attract the sample 110 onto the sample resting surface of the sample holder 100. In this embodiment, while the sample 110 is electrostatically immobilized with the high frequency power supplied to develop a bias potential, that is, at least during processing, inert gas to suppress the adhesion of byproduct particles is introduced near around the outer periphery of the sample 110. According to this embodiment, therefore, the inert gas to suppress the adhesion of byproduct particles is continuously supplied from the time somewhere between the instant (at instant 601) that the electrostatic attraction of the sample 110 is initiated and the instant (at instant 602) that high frequency power is supplied to the electrode in the sample holder 100, up to the time somewhere between the instant (at instant 605) that the supply of the high frequency power is stopped at the completion of processing and the instant (at instant 606) that the electrostatic attraction is released when the supply of the DC power for the electrostatic attraction is ceased.

Further, in this embodiment, the power supply to the focus ring 111 (i.e. the power supply to the underlying power supply ring 112) after the start of the supply of the inert gas to suppress the adhesion of byproduct particles, causes the plasma discharge of the supplied inert gas to take place near around the outer periphery of the sample 110. The interaction among the charged particles, the reactive particles in the plasma and the surface of the sample 110 allows to remove byproducts deposited on or to suppress the adhesion of byproducts onto, the lower surface of the outer periphery of the sample 110.

Depending on the sorts of layers to be processed or optimal process conditions, the shapes of the etched layers on the surface of the sample 110 are sometimes properly controlled by introducing such gas as forming strongly adhesive substance into the process chamber 50 through the shower plate 60 during the processing the layers as shown in FIG. 6D. For example, in case of forming a groove by etching, gas including organic components (e.g. CxHy or CxHyOz) is used to form a deep (having a high aspect ratio) groove in which the width is uniform in the depth direction, by promoting etching in the depth direction while suppressing etching of side walls of the groove.

When such gas as controlling the shapes of the etched layers (shape-control gas) is injected, plasma discharge occurs near the outer periphery of the sample 110 due to injection of the gas to form highly adhesive substance if power is being supplied to the focus ring 111. Consequently, adhesion of substances on and along the outer periphery of the sample 110 further increases. Moreover, since the adhesive substances deposit especially on the lower surface of the outer periphery of the sample 110, the distribution of deposited substances on the upper surface of the sample 110 may deviate from the expected distribution, whereby the resulted dimensions of layers becomes different from what was expected initially. To avoid such an unwanted result in this embodiment, plasma formation near the outer periphery of the sample 110 is suppressed (at instant 603) by reducing the difference between the bias potential over the upper surface of the sample 110 and the bias potential over the upper surface of the focus ring 111.

In this embodiment, as shown in FIG. 6E, the supply of high frequency power to the power supply ring 112 and therefore to the focus ring 111 is stopped while the shape-control gas is being injected, but since control is only necessary to reduce the difference between the bias potential over the upper surface of the sample 110 and the bias potential over the upper surface of the focus ring 111, the supply of high frequency power to the power supply ring 112 need not be stopped but may be reduced.

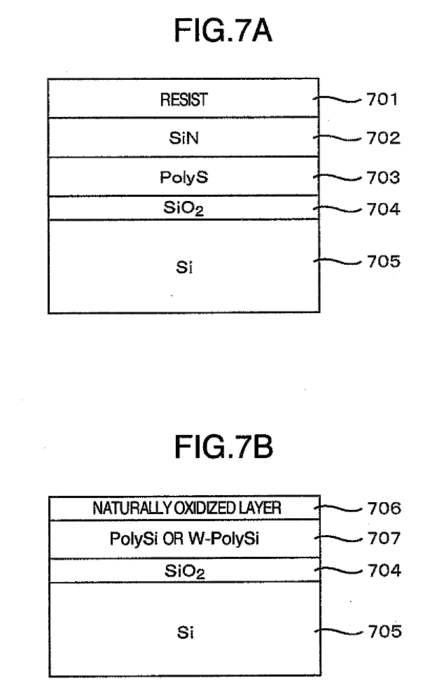

An example of layer structure as formed by the process illustrated in FIGS. 6A through 6E, will now be described with reference to FIGS. 7A and 7B. FIG. 7A shows an example of a layer structure including a hard mask. On a Si substrate are formed, in stack one upon another, a SiO₂ layer 704, a polySi layer 703, a SiN layer 702 serving as a hard mask, and a resist layer 701 serving as a mask for properly controlling the processed shape of the SiN layer 702, in this order mentioned from bottom. The resist layer 701 may be either of photoresist and ArF resist layers.

In the case where the layer structure having plural layers stacked one upon another as shown in FIG. 7A is continuously etched, not only a gas for etching the lower layer, e.g. SiN layer 702, is used, but also a gas for fattening the side wall of the concavity in the resist layer 701 by depositing on the side wall is additively used. The reason for this is as follows. In the initial stage of etching, if the gas for etching the SiN layer 702 is used alone, the speed of etching the resist layer 701 in the horizontal direction is greater than the speed of etching the SiN layer 702 (selectivity ratio is small). Accordingly, the resist layer 701 is excessively etched in the horizontal direction with the result that the desired mask shape of the resist layer 701 for properly etching the SiN layer 702 underlying the resist layer 701 is adversely deformed. To prevent this excessive etching of the resist layer 701 from taking place in the horizontal direction and to preserve the mask shape of the resist layer 701 during etching, the gas for fattening the side wall of the concavity in the resist layer 701 by depositing on the side wall must be added. While the fattening gas is being added, the supply of power to the focus ring 111 or the power supply ring 112 is so controlled that the difference between the bias potential at the surface of the focus ring 111 and the bias potential at the surface of the sample 110 may be reduced to a small value or even zero. Consequently, the generation of plasma is suppressed in the space near the sample outer periphery which is rich in gas that leads to the creation of adhesive particles when turned into plasma, thereby reducing the adhesion of byproducts to the outer periphery of the sample 110 that is a semiconductor wafer.

In the process of the SiN layer 702 which serves as a hard mask, etching is performed with a reactive gas suitable for etching the SiN layer 702, with a little or no addition thereto of a shape control gas for causing depositing on desired surfaces. In this case, the supply of power to the focus ring 111 is such that the difference between the bias potential at the sample 110 and the bias potential at the focus ring 111 may be large, as indicated at instant 604 in FIG. 6, so as to give rise to plasma from the inert gas supplied near around the outer periphery of the sample 110.

In the case of etching the PolySi layer 703 that is formed into a gate structure, the layer 703 is etched faster than the SiN layer 702 serving as a mask and also the horizontal etching tends to be promoted. Therefore, gas causative of deposition must be supplied sufficiently into the process chamber 50 so that the side etching of the layer 703 may be suppressed. In this case, too, the bias potential at the focus ring 111 is so controlled as in the case of processing the resist layer 701.

The above described processing can be applied to a layer structure having a naturally oxidized layer that is formed into a gate structure shown in FIG. 7B, in addition to the layer structure having a hard mask shown in FIG. 7A. This layer structure shown in FIG. 7B differs from the layer structure shown in FIG. 7A in that a PolySi or W-PolySi layer 707 is deposited on the SiO₂ layer 704 as shown in FIG. 7A and also a naturally oxidized layer 706 is formed on the PolySi or W-PolySi layer 707. In the etching process for this layer structure shown in FIG. 7B, during the process of the naturally oxidized layer 706 that is performed in the initial stage of etching, etching is carried out with etching-only gas alone or with etching-only gas mixed with a small amount of deposition-causing gas.

In this case, the supply of power to the focus ring 111 is such that the difference between the bias potential at the sample 110 and the bias potential at the focus ring 111 may be large so as to facilitate the generation of plasma near around the outer periphery of the sample 110. Consequently, not only the speed of etching the outer periphery of the sample 110 can be made uniform, but also the impinging angles of the charged particles (i.e. etching angles) perpendicular to the surface of the sheaths (equipotential surfaces) can be made uniform all over the upper surface of the sample including the peripheral area. Thus, the uniform etching of the sample surface can extend up to the peripheral edge of the sample 110.

In the process of PolySi layer 707 that is formed into a gate structure, a sufficient amount of shape control gas for creating adhesive substance is added to etching-only gas so as to avoid excessively etching in the horizontal direction the layer whose side surface is easy to etch. During this etching, the supply of power to the focus ring 111 is so controlled that the difference between the bias potential at the surface of the focus ring 111 and the bias potential at the surface of the sample 110 may be reduced to a small value or that the supply of power to the focus ring 111 is stopped. Consequently, the generation of plasma is suppressed in the space near the sample outer periphery which is rich in gas that leads to the creation of adhesive particles when turned into plasma, thereby reducing the adhesion of byproducts to the outer periphery of the sample 110.

In this embodiment, the supply of power to the focus ring 111 is controlled depending on the sorts of layers to be processed or the processing conditions. Alternatively, the supply of inert gas may be controlled depending on the sorts of layers to be processed or the processing conditions.

The processing technique described above can be applied to any layer structure where plural layers are stacked one upon another and they include at least one etching-hard layer. According to this embodiment, the adhesion of byproducts to the sample 110 can be suppressed. Namely, plasma is generated from inert gas supplied near around the outer periphery of the sample 110 and the deposition of the byproducts onto the outer periphery of the sample 110 is suppressed through the interaction between the plasma and the byproducts. Further, according to the above described embodiment, the capability of removing the adhesive byproducts can be controlled depending on the variation of process conditions and moreover the capability of uniformly removing the adhesive byproducts within a certain surface area can also be attained.

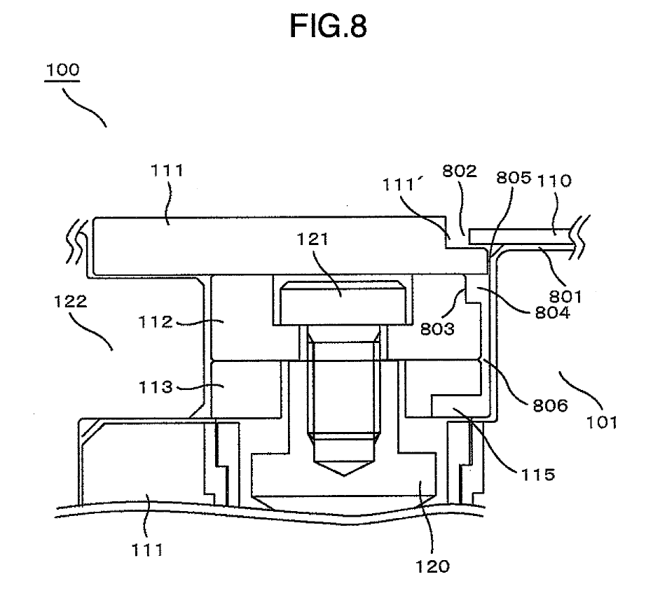

FIG. 8 schematically shows in vertical cross section the structure of a plasma processing apparatus as another embodiment of this invention. In this invention, the power supply ring 112 is provided with an area where plasma is easy to form and the pressure of the area is kept higher than the pressure of the surrounding area. That part of the inert gas passage defined between the gas feed line 115 and the lower surface of the outer periphery of the sample 110 which is located between the inner periphery of the focus ring 111 and the side wall of the top portion of the sample holder 100, is made narrower than the other part of the passage so that the resistance to the inert gas flow is greater at the former part than at the latter part of the inert gas passage. Accordingly, plasma is smoothly generated in the area where plasma is easy to form. The radicals formed in the area are carried along with the inert gas into the space around the lower periphery of the sample 110, remove the adhesive substances deposited on the lower surface of the sample 110, and thus reduce the accumulation of the adhesive substances onto the lower surface of the sample 110.

In this embodiment, a recess 803 is provided in the upper portion of and entirely along, the inner periphery of the power supply ring 112. When the power supply ring 112 with this recess 803 is placed on the base 101 and when the focus ring 111 is placed on the power supply ring 112, a space 804 is formed which has a radial gap greater than that of the space 806 formed between the inner side wall, except the side wall of the recess 803, of the power supply ring 112 and the side wall of the top portion of the sample holder 100. The inner surface of the recess 803 of the power supply ring 112 is covered by a film made of the same material as the dielectric film 801 which covers the side wall of the top portion of the sample holder 100 and also the upper surface of the top portion of the sample holder 100 which serves as the sample resting surface. This film prevents the power supply ring 112 from being damaged by corrosion and abrasion with plasma generated in the space 804.

The gap between the side wall of the power supply ring 112 in the recess 803 and the side wall of the top portion of the sample holder 100 is greater than the gap 806 between the top portion of the sample holder 100 and the lower part of the inner side wall of the power supply ring 112 or the inner side wall of the insulation ring 113. Further, the gap 805 between the innermost sidewall of the focus ring 111 and the side wall of the top portion of the sample holder 100 is still smaller than the gap 806. Accordingly, most part of the inert gas flowing from the gas feed line 115 to the recess 803 momentarily stagnates in the recess 803 and then flows into the space 802 defined by the recess 111′ (referred to also as counterbore in FIGS. 3 and 4) in the inner periphery of the focus ring 111 and the outer periphery of the sample 110 through a narrower gap 805. With this gas passage structure, the inert gas fills the space 804 uniformly and the pressure in the space 804 is made higher than the pressure in the surrounding space.

Under this condition, the space 804 is supplied with the electric field developed due to the potential difference between the focus ring 111 supplied with the high frequency power and the base of the sample holder 110 or the electrode disposed in the dielectric film 801 serving as the sample resting surface and supplied with a DC power to electrostatically attract the sample 110, so that plasma is generated in the space 804. Highly reactive particles such as radicals formed in the plasma are transferred with gas flow into the space 802 as described above and interact there with adhesive substances deposited on the outer periphery of the sample 110 so that the accumulation of the adhesive substance on the outer periphery of the sample 110 is suppressed. Further, by allowing gas to flow from the space 804 of high pressure to the space 802 of low pressure, the deposition of adhesive substances onto the lower surface of the sample 110 can be reduced. It is noted here that the recess 803 can be provided not only in the upper portion of the inner periphery of the power supply ring 112, but also in the lower portion of the inner periphery of the power supply ring 112.

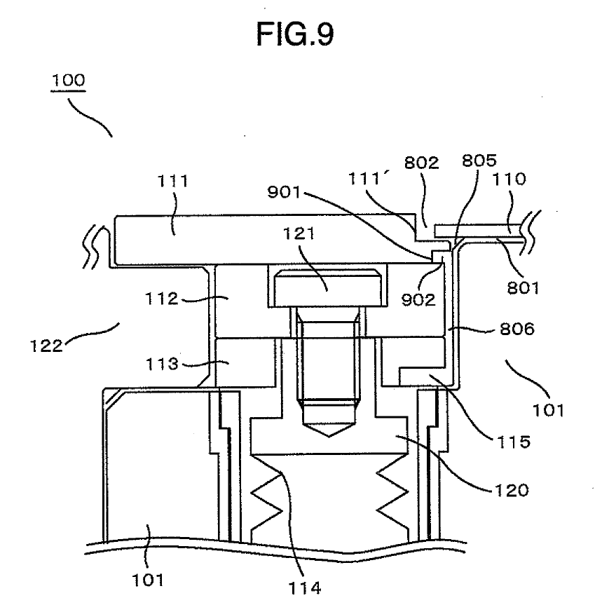

An example wherein such a space to generate plasma therein is provided in the inner periphery of the focus ring 111 will be described below with reference to FIG. 9. The difference of this example from the embodiment shown in FIG. 8 is that a recess 901 serving as a space in which plasma is generated is provided in the lower portion of the inner periphery of the focus ring 111 while the recess 111′ is formed in the upper portion of the inner periphery of the focus ring 111, as shown in FIG. 9.

In this example, too, the gap 805 is narrower than the gap 806 so that gas supplied from the gas feed line 115 may stagnate in the space 902 and that the pressure in the space 902 may become high. With this gas passage structure, the space 902 is supplied with the electric field developed due to the potential difference between the focus ring 111 or the power supply ring 112 and the base of the sample holder 110 or the electrode disposed in the dielectric film 801 serving as the sample resting surface and supplied with a DC power to electrostatically attract the sample 110, so that plasma is generated in the space 902. Highly reactive particles such as radicals formed in the plasma are transferred with gas flow into the space 802 as described above and interact there with adhesive substances deposited on the outer periphery of the sample 110 so that the accumulation of the adhesive substance on the outer periphery of the sample 110 is suppressed.

In the above described embodiments and the above example, in order to enhance the generation of plasma in the spaces 804 and 902, the surface of the dielectric film 801 covering the side surface of the top portion of the sample holder 100 is so processed as to be provided with micro-projections. For example, the dielectric film 801 is formed on the side surface of the top portion of the sample holder 100 by using thermal spray coating technique and then subjected to blasting to provide its surface with as many micro-projections as possible. Accordingly, the thus formed dielectric film 801 having so many micro-projections on its surface will enhance the surface electron emission capability of the dielectric film 801 and facilitate the generation of plasma.

The plasma generated between the focus ring 111 and the dielectric film 801 on the side wall of the top portion of the sample holder 100, stems from the emission of electrons and therefore an important role is played by the leak current resulting from the AC power supplied to the electrode disposed in the base 101 of the sample holder 100 or from the DC power supplied to the electrode disposed for electrostatic attraction in the dielectric film 801. To keep the leak current flowing incessantly facilitate the generation and sustention of plasma. For this purpose, for example, DC power is supplied to the electrode disposed for electrostatic attraction in the dielectric film 801 so as to maintain the electrode at a desired fixed potential while high frequency power is supplied to the focus ring 111 or the power supply ring 112 such that the fixed potential at the electrode may lie between the peak and the trough of the waveform of the high frequency power. Namely, the voltage resulting from superposing an AC voltage upon the DC voltage applied to the electrode may be applied to the focus ring 111. Accordingly, the gradient of potential periodically changes on the higher and lower sides of the DC potential so that the motion of electrons periodically reciprocates in the space 804 or 902.

The means for generating plasma used for the process described in the foregoing embodiments and example is not limited to those mentioned in the foregoing description, but may be such a means as ECR using capacitive coupling, inductive coupling or UHF waves. In the foregoing embodiments and example, a plasma processing apparatus for performing etching treatment was described, but this invention can equally be applied to a variety of apparatuses for processing samples with or without plasma while being heated in the depressurized atmosphere. For example, the processing apparatus using plasma includes a plasma etching apparatus, a plasma CVD apparatus, a sputtering apparatus, etc. On the other hand, the process which does not use plasma includes ion implantation, MBE, vapor deposition, depressurized CVD, etc.

It should be further understood by those skilled in the art that although the foregoing description has been made on embodiments of the invention, the invention is not limited thereto and various changes and modifications may be made without departing from the spirit of the invention and the scope of the appended claims.

1. (canceled)

2. A plasma processing apparatus, comprising:
a vacuum vessel which has a processing chamber in which a semiconductor wafer to be processed is placed;
a sample holder which is disposed within the processing chamber, the wafer being disposed within the processing chamber, the wafer being disposed on an upper surface of the sample holder;
a ring-shaped member which is disposed so as to surround an outer side periphery of the sample holder;
a gas supply opening which is disposed at the outer side periphery side of the sample holder so as to supply gas therefrom; and
a gas flowing path which flows the gas supplied from the gas supply opening toward an upper end portion of the sample holder along the outer side periphery side of the sample holder;
wherein the gas flowing path includes a gas flow opening which is disposed between the ring-shaped member and an outer periphery of the upper end portion of the sample holder so as to surround the outer side periphery of the upper end portion with a gap of a first dimension between the outer side periphery of the upper portion and the ring-shaped member, and a ring-shaped space which is disposed between the gas flow opening and the gas supply opening so as to surround the outer side periphery of the sample holder with a width of a second dimension which is larger than the first dimension of the gap.

3. A plasma processing apparatus according to claim 2, wherein the gas flowing path further includes another space which is disposed between the ring-shaped space and the gas supply opening so as to communicate therewith a width of a third dimension which is smaller than the width of the second dimension of the ring-shaped space.

4. A plasma processing apparatus according to claim 2, wherein the gas flowing path is formed by a gap between the ring-shaped member and the outer side periphery of the sample holder, and the gas supply opening is disposed at the outer side periphery of the sample holder.

5. A plasma processing apparatus according to claim 2, wherein the ring-shaped member is formed by a ring-shaped conductive material to which a high-frequency electric power is supplied.

6. A plasma processing apparatus according to claim 4, wherein the ring-shaped member is formed by a ring-shaped conductive material to which a high-frequency electric power is supplied.

7. A plasma processing apparatus according to claim 2, wherein plasma is generated within the gas flowing path.

8. A plasma processing apparatus according to claim 4, wherein plasma is generated within the gas flowing path.

9. A plasma processing apparatus according to claim 5, wherein plasma is generated within the gas flowing path.
